(19) United States
(12) Patent Application Publication
(10) Pub. No.: US 2003/0007328 A1
(43) Pub. Date: Jan. 9, 2003

(54) Cooling device for electronic components

(76) Inventor: Ulrich Fischer, Leutkirch (DE)

Correspondence Address: Womble Carlyle Sandridge & Rice, PO Box 7037, Atlanta, GA, 30357-0037, US

(21) Appl. No.: 09/980,320

(22) PCT Filed: Mar. 8, 2001
(86) PCT No.: PCT/EP01/02631

(30) Foreign Application Priority Data
Mar. 16, 2000 (DE) 100 12 999.0.

(51) Int. Cl. H05K 7/20

(52) U.S. Cl. 361/704; 165/185; 428/901

(57) ABSTRACT

The present invention relates to a cooling device for electronic components, in particular for cooling microprocessors, which has at least one passive thermo-conducting cooling element 12, wherein at least part of said passive cooling element 12 contacts at least one heat transfer medium 20 which is in a solid state of aggregation. Said heat transfer medium 20 in this case is a phase change material (PCM) which has a much higher heat absorption capacity than water and which is, moreover, designed as a latent heat accumulator, which heat transfer medium 20 will store the amount of heat generated by the load on said electronic component that can no longer be absorbed and carried off by said passive cooling element 18, at the same time retaining its solid state of aggregation, and release said heat again at a time when the load on said electronic component is lower.

The present invention relates to a cooling device for electronic components, in particular for cooling microprocessors, which has at least one passive thermo-conducting cooling element.

A wide variety of electronic component cooling devices of this type are known in the prior art. These especially comprise passive thermo-conducting cooling elements, in particular made of aluminum, which are mounted on the surfaces of said electronic components, thus effectively contacting them. The cooling elements are attached thereto by means of adhesive or special supports. Usually, there is also an additional active cooling element in the form of a fan, which is either positioned on said passive cooling elements or integrated within said passive cooling elements.

The prior art cooling systems are all based on the principle of heat transfer by evaporation, condensation, convection and dissipation, or they are characterized by different material combinations and surface structures of different thermo-conducting capacities and/or thermal resistances

A disadvantage of the prior art cooling devices, however, is that in view of the ever more powerful electronic components, in particular due to the higher and higher microprocessor clock rates, the development of heat also increases strongly. Since such electronic components will only function properly in a certain temperature range, however, and too high temperatures will cause them to either become inoperative or lose considerable power, ever increasing demands are also made on the respective cooling devices. The above mentioned coolers of the prior art are no longer capable of achieving the desired and required degree of cooling.

Therefore, it is the object of the present invention to provide a cooling device for electronic components, in particular for cooling microprocessors, which has at least one passive thermo-conducting cooling element, which device will ensure sufficient cooling of the electronic components even in case of a strong heat build-up.

This object is accomplished by a generic cooling device having the features of claim 1.

Advantageous embodiments are described in the subclaims.

An inventive cooling device for electronic components includes at least one passive thermo-conducting cooling element, with at least part of said passive cooling element contacting at least one heat transfer medium which is in a solid aggregation state. Said heat transfer medium in this case is a phase change material (PCM) which has a much higher heat capacity than water, for example. Moreover, said heat transfer medium has been designed as a latent heat accumulator to store the amount of heat generated by the load on the electronic component that can no longer be absorbed and carried off by said passive cooling element, at the same time maintaining its solid state of aggregation, and release said heat again at a time when there is a lower load on the electronic component. This will ensure that electronic components, in particular microprocessors, will be sufficiently cooled even if there is a high load and a corresponding high heat build-up. At the same time, the heat transfer medium is capable of absorbing temporarily occurring additional amounts of heat and of releasing them again once the load is back to normal, i.e. the electronic component develops a normal amount of heat again. Peak thermal loads are thus avoided which usually clearly diminish the power of the electronic component and especially that of a microprocessor when conventional cooling devices are used. Consequently, the inventive cooling device also allows an increase in power of the cooled components. Avoiding damaging peak heat loads will furthermore increase the working life and the operativeness of the electronic components cooled by means of the cooling device of the invention. Since the phase change material used as a heat transfer medium will retain its solid state of aggregation also during heat absorption, there will advantageously not be any problems due to an expansion of the phase change material, as opposed to what is always the case with known materials.

In an advantageous embodiment of the cooling device of the invention, the heat transfer medium consists of salts or salt mixtures enriched with organic substances as well as of substances in the form of fine metallic powders for improving the thermo-conducting capacity. Usually, the organic ingredient of the heat transfer medium is paraffin. A heat transfer medium of this kind will also retain its solid state of aggregation during heat absorption, and may thus be mounted in the form of a tablet or pellet and/or as a solid body within and/or on said cooling element. This will allow said cooling device to be manufactured economically, on the one hand, and, on the other hand, it will ensure that it can be kept small in size. Moreover, it is possible according to the invention to individually adjust the heat transfer medium to the required operational temperatures for cooling the electronic components. Such adjustment is done by varying the kind and amount of the ingredients of the heat transfer medium. In particular, it is also possible to adjust the amount of heat to be buffered by the heat transfer medium. Moreover, another advantage of said heat transfer medium is that it is non-toxic as well as recyclable.

In an advantageous embodiment of the cooling device of the invention, the passive cooling element includes at least one active cooling element, in particular a fan. This will advantageously ensure a further increase of the cooling power of the cooling device.

In yet another advantageous embodiment of the cooling device of the invention, the heat transfer medium is accommodated in a container made of thermo-conducting material, said container contacting said passive cooling element. Providing said heat transfer medium within a container will allow easy replacement of the individual heat transfer elements mounted within or on said passive cooling element.

In yet another advantageous embodiment of the cooling device of the invention, a thermo-conducting foil is provided between a contact surface of said passive cooling element and a corresponding contact surface of said electronic component. This measure will ensure that the total cooling power achieved by means of said cooling device is increased further by an optimized heat transfer from the electronic component to the passive cooling element.

The invention furthermore relates to a processor with a processor socket and at least one cooling device mounted on said processor, which cooling device includes at least one passive thermo-conducting cooling element, with at least part of said passive cooling element contacting at least one heat transfer medium which is in a solid state of aggregation. In this case, the heat transfer medium is a phase change material (PCM) which has a much higher heat absorption capacity than water for example. Moreover, said heat transfer medium has been designed as a latent heat accumulator so as to store the amount of heat generated by the load on the processor that can no longer be absorbed and carried off by the passive cooling element, at the same time retaining its solid state of aggregation, and to release said heat again at a time when there is a smaller load on the processor.

The invention furthermore relates to the use of a heat transfer medium, which is in a solid state of aggregation, for cooling microprocessors, said heat transfer medium being a phase change material (PCM) that has a much higher heat absorption capacity than water and has been designed as a latent heat accumulator. The heat transfer medium will store the amount of heat generated by the load on the microprocessor, at the same time retaining its solid state of aggregation, and release said heat again at a time when the load on the microprocessor is smaller.

Further details, features and advantages of the present invention may be gathered from an embodiment shown in the attached drawings, of which:

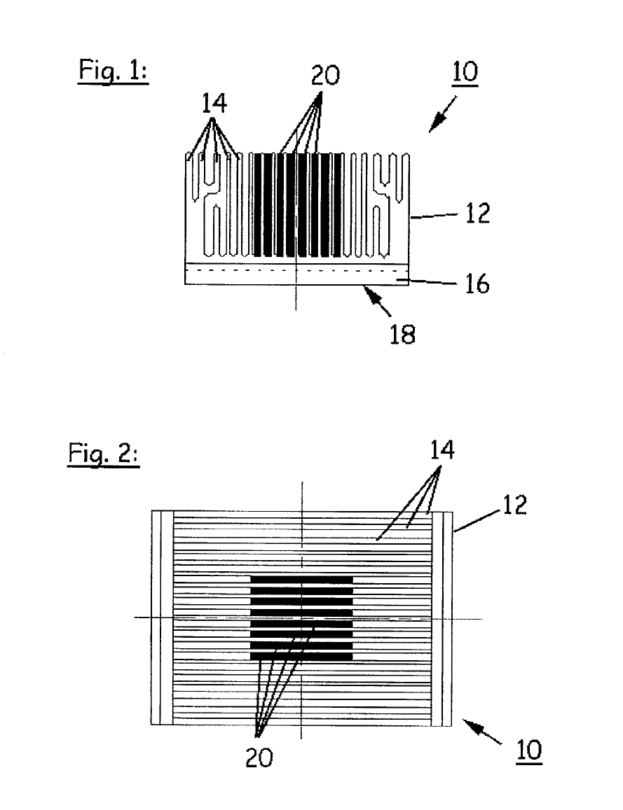

FIG. 1 is a schematic sectional view of a cooling device of the invention;

FIG. 2 is a schematic top view of the cooling device of the invention as shown in FIG. 1; and

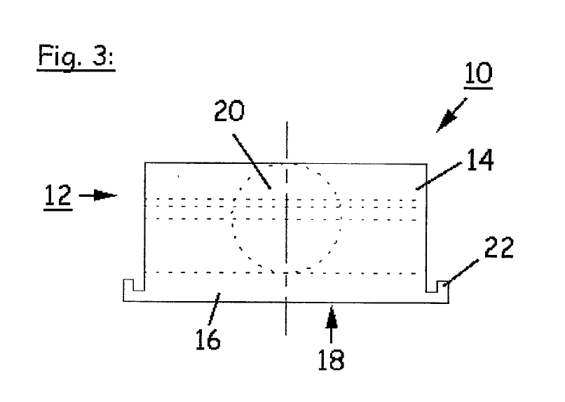

FIG. 3 is a schematic lateral view of the cooling device of the invention as shown in FIG. 1.

FIG. 1 is a sectional view of a cooling device 10 for cooling electronic components, in particular for cooling microprocessors. Said cooling device 10 comprises a passive thermo-conducting cooling element 12, which cooling element 12 consists of a plurality of cooling ribs or fins 14. Said cooling ribs or fins 14 are mounted on a bottom element 16 of said cooling element 12. On the side opposing said cooling ribs or fins 14, said bottom element 16 exhibits a contact surface 18 which contacts the electronic component intended to be cooled.

The passive cooling element 12 is made of aluminum or an aluminum alloy, and is usually a single piece. It can be seen in this drawing that plural heat transfer media 20 are provided between the cooling ribs or fins 14 within said cooling element 12. Said heat transfer media 20 are in a solid state of aggregation and in thermo-conducting contact with said cooling ribs or fins 14 and said bottom element 16 or said cooling element 12, resp. In this case, the heat transfer medium is a phase change material which has a much higher heat absorption capacity than water, for example. Since the heat transfer medium is in a solid state of aggregation which it will also retain during heat absorption, it will not be necessary to provide the heat transfer medium 20 or the cooling element 12 with sealing properties. Supporting the individual heat transfer media 20 within said passive cooling element 12 will suffice. Said heat transfer medium is moreover provided in the form of a PCM device so as to cause said heat transfer medium 20 to store the thermal energy generated by the load on the electronic component that can no longer be absorbed and carried off by the passive cooling element 18, at the same time retaining its solid state of aggregation, and to release said heat again at a time when the load on the electronic component is lower.

FIG. 2 is a schematic top view of the cooling device 10 according to FIG. 1. This drawing shows the arrangement of the individual heat transfer media 20 between the individual cooling ribs or fins 14 of said cooling element 12.

FIG. 3 is a lateral view of the cooling device according to FIG. 1. This drawing shows that said cooling element 12 includes attachment means 22, at the area of said bottom element 16 and on its sides, for attaching said cooling device 10 together with the electronic component to be cooled. Furthermore, one can see that, in the embodiment illustrated, the heat transfer media 20 are provided in the form of disks. However, the size and shape of said heat transfer media 20 may be chosen at random. The size and the number of said heat transfer media 20 will allow, amongst other things, the adjustment of the required operational temperatures for the respective electronic components intended to be cooled.

What is claimed is:

1. A cooling device for electronic components, in particular for cooling microprocessors, which has at least one passive thermo-conducting cooling element (12)
characterized in
that at least part of said passive cooling element (12) contacts at least one heat transfer medium (20) which is in a solid state of aggregation, which heat transfer medium (20) is a phase change material (PCM) that has a much higher heat absorption capacity than water and that has been designed as a latent heat accumulator, which heat transfer medium (20) will store the amount of heat generated by the load on the electronic component that can no longer be absorbed and carried off by said passive cooling element (2), at the same time retaining its solid state of aggregation, and release said heat again at a time when the load on said electronic component is lower.

2. The cooling device as claimed in claim 1
characterized in
that said heat transfer medium (20) consists of inorganic salts or salt mixtures enriched with organic substances, as well as of substances in the form of fine metallic powders for improving the conducting capacity

3. The cooling device as claimed in claim 2
characterized in
that said organic ingredient of said heat transfer medium (20) is paraffin.

4. The cooling device as claimed in one of the preceding claims
characterized in
that said heat transfer medium (20) can be adjusted to the required operational temperatures.

5. The cooling device as claimed in one of the preceding claims
characterized in
that said heat transfer medium (20) is provided within and/or on said cooling element (12) in the form of a tablet or pellet and/or as a solid body.

6. The cooling device as claimed in one of the preceding claims
characterized in
that said heat transfer medium (20) is non-toxic as well as recyclable.

7. The cooling device as claimed in one of the preceding claims
characterized in
that said passive cooling element (12) is made of aluminum or of an aluminum alloy.

8. The cooling device as claimed in one of the preceding claims
characterized in
that at least one active cooling element is provided on said passive cooling element (12).

9. The cooling device as claimed in claim 8
characterized in
that said active cooling element is a fan.

10. The cooling device as claimed in one of the preceding claims
characterized in
that said heat transfer medium (20) is accommodated in a container of thermo-conducting material, said container contacting said passive cooling element (12).

11. The cooling device as claimed in one of the preceding claims
characterized in
that a thermo-conducting foil is provided between one contact surface (18) of said passive cooling element (12) and a corresponding contact surface of said electronic component.

12. A processor with a processor socket and at least one cooling device mounted on said processor
characterized in
that said cooling device (10) includes at least one passive thermo-conducting cooling element (12), with at least part of said passive cooling element (12) contacting at least one heat transfer medium (20) which is in a solid state of aggregation, said heat transfer medium (20) being a phase change material (PCM) which has a much higher heat absorption capacity than water, and which is designed as a latent heat accumulator, which heat transfer medium (20) will store the amount of heat generated by the load on the processor that can no longer be absorbed and carried off by the passive cooling element (18), at the same time retaining its solid state of aggregation, and release said heat again at a time when the load on the processor is lower.

13. Use of a heat transfer medium, which is in a solid state of aggregation, for cooling microprocessors, said heat transfer medium being a phase change material (PCM) which has a much higher heat absorption capacity than water, and which is designed as a latent heat accumulator, which heat transfer medium will store the amount of heat generated by the load on the microprocessor, at the same time retaining its solid state of aggregation, and release said heat again at a time when the load on the processor is lower.
